(19) United States
(12) Patent Application Publication
(10) Pub. No.: US 2026/0053009 A1
(43) Pub. Date: Feb. 19, 2026

(54) SEMICONDUCTOR PACKAGES AND RELATED METHODS TO ENABLE WETTABLE FLANKS

(71) Applicant: SEMICONDUCTOR COMPONENTS INDUSTRIES, LLC, Scottsdale, AZ (US)

(72) Inventor: Arvin SALUM, Tarlac City (PH)

(73) Assignee: SEMICONDUCTOR COMPONENTS INDUSTRIES, LLC, Scottsdale, AZ (US)

(21) Appl. No.: 18/808,415

(22) Filed: Aug. 19, 2024

(51) Int. Cl. H01L 23/495; H01L 21/48; H01L 21/56; H01L 23/00

(52) U.S. Cl. CPC H01L 23/49551; H01L 21/4842; H01L 24/97; H01L 21/561; H01L 24/85; H01L 2224/85986; H01L 2224/97

(57) ABSTRACT

Implementations of a substrate may include a first set of tie bars; a second set of tie bars; and a plurality of leads coupled between the first set of tie bars and the second set of tie bars. The first set of tie bars may intersect with the second set of tie bars. Each intersection of the first set of tie bars and the second set of tie bars may be downset from the plurality of leads.

### BACKGROUND

### 1. Technical Field

Aspects of this document relate generally to semiconductor packages, such as packages for semiconductor die.

### 2. Background

Semiconductor packages have been devised that work to provide electrical connections between a semiconductor die and motherboard or circuit board to which the semiconductor package is attached. Various semiconductor packages provided protection from humidity or mechanical support for a semiconductor die. Other semiconductor packages work to protect the semiconductor die from shock or vibration.

### SUMMARY

Implementations of a substrate may include a set of intersecting tie bars forming a grid pattern, wherein each intersection in the set of intersecting tie bars may be downset from a plurality of leads coupled within the grid pattern of the set of intersecting tie bars.

Implementations of a substrate may include one, all, or any of the following:
The first group of the set of intersecting tie bars may be oriented substantially perpendicularly to a second group of the set of intersecting tie bars.
The thickness of the set of intersecting tie bars and the plurality of leads may be less than 0.2 mm.
The downset may be 0.08 mm or larger.

Implementations of a substrate may include a first set of tie bars; a second set of tie bars; and a plurality of leads coupled between the first set of tie bars and the second set of tie bars. The first set of tie bars may intersect with the second set of tie bars. Each intersection of the first set of tie bars and the second set of tie bars may be downset from the plurality of leads.

Implementation of a substrate may include one, all, or any of the following:
The first set of tie bars and the second set of tie bars intersect substantially perpendicularly.
The thickness of the first set of tie bars and of the second set of tie bars may be less than 0.2 mm.
The thickness of the plurality of leads may be less than 0.2 mm.
The downset may be 0.08 mm or larger.

Implementations of a method of forming a semiconductor package may include providing a substrate that may include a first set of tie bars; a second set of tie bars; and a plurality of leads coupled between the first set of tie bars and the second set of tie bars. The first set of tie bars and the second set of tie bars may be downset at a plurality of intersections. The method may include coupling a semiconductor die to the plurality of leads; applying an electrically insulative material over the substrate; forming a channel in the electrically insulative material and forming a flank in each of the plurality of leads. The method may include electroplating the flank of each of the plurality of leads, and singulating a semiconductor package through cutting the first set of tie bars and second set of tie bars.

Implementations of a method of forming a semiconductor package may include one, all, or any of the following:
Electroplating the flank of each of the plurality of leads further may include electroplating using the first set of tie bars and the second set of tie bars.
Forming the flank in each of the plurality of leads further may include cutting entirely through a thickness of each of the plurality of leads.
Forming the channel in the electrically insulative material further may include partially cutting into the material of the electrically insulative material.
Forming the channel in the electrically insulative material further may include not cutting the downset of the plurality of intersections.
Singulating the semiconductor package further may include cutting the channel in the electrically insulative material.
The substrate may be a leadframe.
The leadframe may be a panel.
The semiconductor package may be a leadless semiconductor package.
After electroplating, the flank of each of the plurality of leads may be a solder wettable flank.
Electroplating the flank of each of the plurality of leads further may include electroplating the entire flank.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a top view of an implementation of a substrate;

FIG. 2 is a perspective view of the substrate implementation of FIG. 1;

FIG. 3 is a partial see through view of a substrate implementation after application of an electrically insulative material thereto and cutting of channels therein;

FIG. 4 is a perspective view of the substrate implementation of FIG. 3 following an electroplating operation;

FIG. 5 is a perspective view of a plurality of semiconductor packages following singulation;

FIG. 6 is a cross sectional view of a semiconductor package implementation coupled to a motherboard using solder fillets;

FIG. 7 is a perspective view of an implementation of a substrate with semiconductor die coupled thereto;

FIG. 8 is a perspective view of the substrate implementation of FIG. 7 following formation of electrical connections between the substrate and the semiconductor die;

FIG. 9 is a perspective view of the substrate of FIG. 8 following application of an electrically insulative material thereto;

FIG. 10 is a perspective view of a bottom/lead side surface of the substrate implementation of FIG. 9;

FIG. 11 is a perspective view of the substrate implementation of FIG. 10 following formation of channels in one direction therein;

FIG. 12 is a perspective view of the substrate implementation of FIG. 11 following an electroplating operation; and

FIG. 13 is a perspective view of a plurality of semiconductor packages following a singulation operation.

### DESCRIPTION

This disclosure, its aspects and implementations, are not limited to the specific components, assembly procedures or method elements disclosed herein. Many additional components, assembly procedures and/or method elements known in the art consistent with the intended semiconductor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor packages, and implementing components and methods, consistent with the intended operation and methods.

In various semiconductor package designs, leads are used to form electrical connections between a semiconductor die and a motherboard/circuit board to which the semiconductor package is attached. In package implementations where solder is used to attach the leads to the motherboard/circuit board, the ability of the solder to wet the sides/flanks of the leads during the bonding process affects the strength and quality of the bond. Wettable flanks improve the formation of fillets of solder which help strengthen the bond and are easier to see using optical inspection tools to determine the quality of the bond. Where little to no wetting of the flanks of the leads takes place, reliability issues can arise and the ability to accurately optically inspect the bonds is significantly diminished. Thus, the ability to have wettable flanks for leads for a semiconductor package can improve the package performance post bonding and aid in quality inspection during the assembly process.

The various semiconductor package implementations disclosed herein may be leadless or leaded. “Leadless” in this document includes lead designs where the leads of the semiconductor package do not extend outwardly substantially beyond a surface of an electrically insulative material that surrounds the leads. “Leaded” in this document includes lead designs where the leads extend away from a surface from an electrically insulative material that surrounds the leads. While the examples of semiconductor packages in this document show various leadless designs like ultra dual flat no-lead (UDFN) packages or dual flat no-lead (DFN) packages, the principles disclosed herein can be extended to flanks of leaded packages or other types of packages as well. The principles disclosed herein can be used particularly for chip-on-lead package designs.

Various semiconductor die may be included in the package implementations disclosed herein. These semiconductor die may include various substrate materials including, by non-limiting example, silicon, silicon carbide, silicon-on-insulator, glass, sapphire, ruby, gallium arsenide, gallium nitride, or any other semiconductor material type. The semiconductor die may also include various semiconductor device types, including, by non-limiting example, metal oxide field effect transistors (MOSFETs), insulated gate bipolar transistors (IGBTs), diodes, power semiconductor devices, rectifiers, thyristors, or any other semiconductor device type. One semiconductor die may be included in the various semiconductor package implementations, or multiple semiconductor die may be included.

In this document, substrates are used as part of the semiconductor package design to allow for routing of electrical signals from the semiconductor die to the motherboard/circuit board and to provide mechanical support for the semiconductor die. While the substrate types illustrated in the figures in this document reflect that the substrate is a leadframe, strip of leadframes, or panel of leadframes, the principles disclosed herein could also be applied to leadframe types, such as, by non-limiting example, printed circuit boards, laminated substrates, insulated metal substrates, or other substrate types.

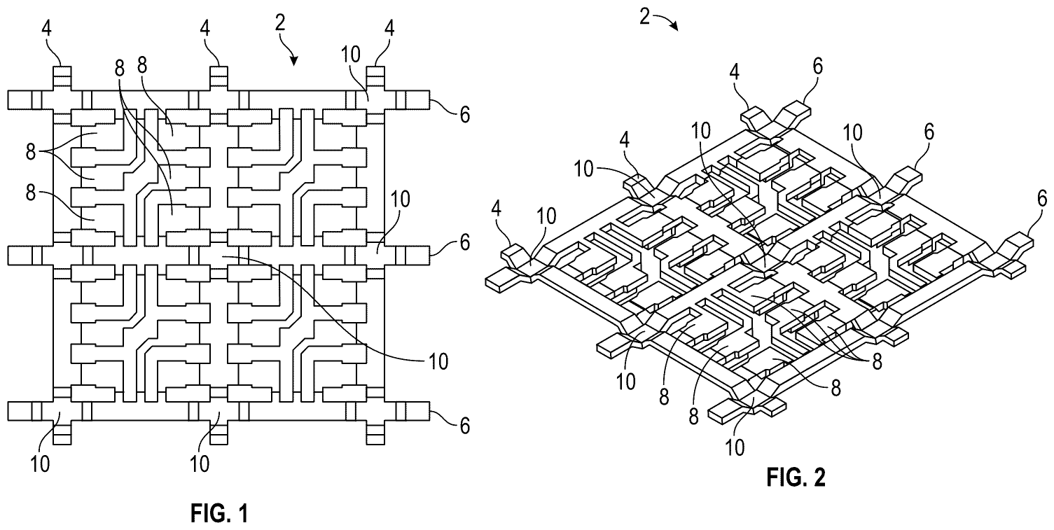

Referring to FIGS. 1 and 2, an implementation of a substrate 2 is illustrated. In this implementation, the substrate 2 is a leadframe that is composed of an electrically conductive material like a metal or metal alloy. As illustrated, a set of first tie bars 4 and second tie bars 6 are part of the leadframe in a spaced apart manner forming a grid with spaces in which leads 8 are coupled to the tie bars 4, 5. As illustrated, the first set of tie bars 4 intersect with the second set of tie bars, in this implementation substantially perpendicularly to one another to form a set of intersections 10.

Referring to FIG. 2, this perspective view of the leadframe 2 shows how, at each of the plurality of intersections 10, the intersection is downset or at a lower level than the rest of the material of each tie bar of the first set of tie bars 4 and second set of tie bars 6. The intersections 10 are also downset relative to a level of the plurality of leads 8 of the leadframe 2. As illustrated in FIG. 2, the plurality of leads and the non-downset portions of the tie bars form a plane from which the plurality of intersections 10 are downset.

While in the leadframe implementation of FIGS. 1 and 2 no die flag structure is included, in other implementations, a die flag could be included. Also, while each lead is shown as being attached to just one of the tie bars on an internal side of the lead, in other implementations, the leads could be attached on the internal side of the leads to multiple tie bars. While the leadframe may be made of copper or a copper alloy, a wide variety of electrically conductive materials or layers of electrically conductive materials could be utilized as well, including, by non-limiting example, aluminum, aluminum alloys, silver, silver alloys, tin, tin alloys, nickel, nickel alloys, any combination thereof, or any other electrically conductive material type.

For leadframes or electrical connectors in substrates less than 0.2 mm in thickness it is difficult to create a wettable flank because the thickness of the leadframe is thin enough that utilizing a step cut process to partially expose the flank of the lead prior to electroplating becomes much more difficult. The use of downsetting of the intersections helps aid in utilizing a step cut process as will be disclosed further herein. For example, where a thickness of the leadframe is about 0.123 mm, the downset of the intersections is set at about 0.08 mm or greater so that the desired step cut can be achieved. In various implementations, the depth of the cut/step cut is between about 2% to about 10% of the thickness of the leadframe/electrically conductive layer in the substrate. If, instead of a step cut process, increasing the thickness of the leadframe was carried out (from 128 microns to 256 microns, for example) followed by a etching process to expose the flanks of the leads, the cost of that process would correspondingly increase with the increased thickness of the leadframe. The other technical challenge is that the etching process used may not create the desired flat surfaces of the flanks due to the time involved in etching so much of the leadframe material. This problem may be most acute where wet etching was employed.

In various implementations, the leadframe may be formed by stamping, punching, etching, or cutting the leadframe pattern from a sheet of material followed by downsetting the intersections through a stamping or other bending process. For substrates which are not leadframes, the downset intersections may be formed through laminating, pressing, or forming them through the layer by layer layup process of forming a printed circuit board.

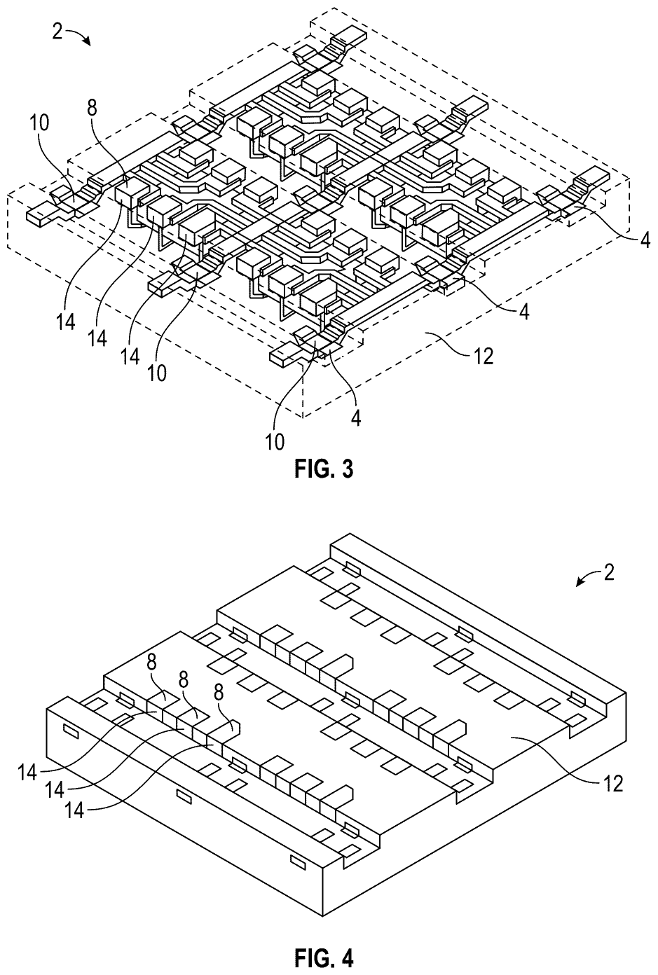

Referring to FIG. 3, the leadframe implementation 2 of FIG. 2 is illustrated following application of an electrically insulative material 12 thereto, leaving surfaces of the leads 8 exposed. In various implementations, the electrically insulative material may be any of a wide variety of materials, including, by non-limiting example, a mold compound, a resin, an encapsulant, a polymer, an epoxy, a filler, a colorant, any combination thereof, or any other electrically insulative material type. FIG. 3 shows the electrically insulative material 12 in a see through manner so the otherwise covered portions of the leadframe 2 can be observed. FIG. 3 illustrates the leadframe 2 following step cutting of the electrically insulative material 12 and the ends of the leads 8 using a sawing or etching process, resulting in a set of exposed flanks 14. Note that the cutting is step cutting that does not cut all the way through the electrically insulative material 12, nor which cuts into or substantially into the intersections 10 of the first set of tie bars 4 and second set of tie bars 6. While the majority of the material of the first set of tie bars 4 has been removed through the cutting operation, the downset portion has not and the material of the second set of tie bars 6 now remains.

Because the second set of tie bars 6 remains physically connected to each of the plurality of leads 8 following the cutting, the portions of the leads that are exposed through the surfaces of the electrically insulative material 12 can be electroplated through the electrical connection that has been created. These portions of the leads 8 also include the exposed flanks 14. As illustrated, because the exposed flanks 8 extend entirely across a thickness of the plurality of leads 8, the entirety of the exposed flanks 14 can be electroplated. This ability to electroplate the entire exposed flank across the full thickness of the lead maximizes the solder wettable surface of the flank and can form solder fillets that cover about 75%, about 80%, about 85%, about 90%, about 95%, or about 100% of the wettable surface of the flank. These solder fillets can then help improve the joint reliability and the optical inspection capability of the bonds. This wettability of the flank is because the entire surface of the flank is exposed during the electroplating process in contrast with partial cut only or dimple-type wettable flank processes which leave only part of the flank exposed.

FIG. 4 illustrates the leadframe 2 with the electrically insulative material 12 following the cutting operation showing the exposed leads 8 and exposed flanks 14. As illustrated, the cutting is just in one channel, along the length of the first set of tie bars and is designed to leave the intersections 10 unexposed through the electrically insulative material. Leaving the intersections 10 unexposed helps reduce the amount of electroplating that takes place on portions of the leadframe that ultimately will be cut away when the leadframe 2 is singulated in the second channel and the tie bars removed.

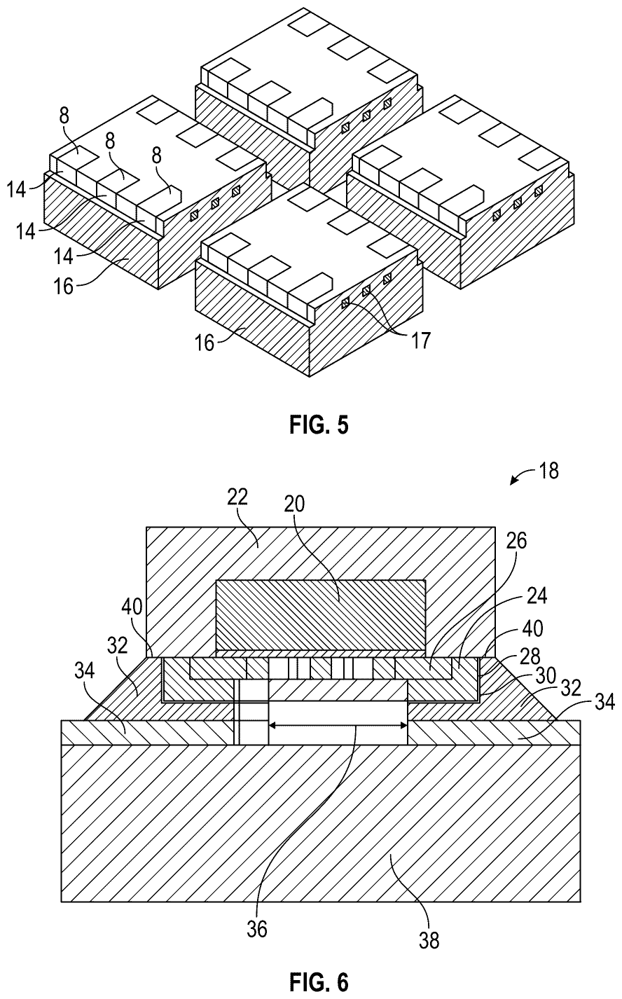

Referring to FIG. 5, a plurality of semiconductor packages 16 is illustrated following singulation of the leadframe 2 of FIG. 4. As illustrated, during singulation, the remaining material of the first set of tie bars 4 is removed and all of the material of the second set of tie bars 6 is removed. The portions 17 of the plurality of leads 8 that attached to the tie bars is also removed and are illustrated as being exposed through the electrically insulative material 12. Also illustrated is how the flanks 14 are fully exposed next to a stepped/flanged portions of the electrically insulative material 12 that remains after cutting of the remaining tie bar and electrically insulative material 12. Because the flanks 14 have been electroplated, the width of the cutting done in the previously cut channel is narrowed to avoid removing/damaging the electroplated flank surfaces through the cutting.

Referring to FIG. 6, an implementation of a semiconductor package 18 is illustrated in a cross sectional view that shows the semiconductor die 20 surrounded by electrically insulative material 22 and coupled to leads 24 and leadframe 26. As illustrated, the flanks 28 of the leads 24 are covered with a coating of electroplated material 30 that aided in wetting the flanks 28 fully with the solder to form solder fillets 32. The ability to form the solder fillets 32 is advantageous in this package implementation because the semiconductor package 18 is attached to copper traces 34 of a circuit board 38 that include a gap 36 between them over which the semiconductor package 18 is bonded. Thus, the tolerance for solder flow into the gap is low, and the need to control solder flow using the wettable flanks 28 prevents internal bridging that would result in a short. Since this semiconductor package 18 is a leadless package, its footprint is correspondingly small, assisting with its bonding in a correspondingly small area of the circuit board 38. Also as illustrated, the stepped/flanged portions 40 of the electrically insulative material 22 adjacent to the flanks 28 assist with creation of the fillet and uniform spreading of the solder to form an optically visible bond and control movement of the solder around the exterior of the package. These stepped/flanged portions 40 may also, through helping to guide solder flow, prevent solder flow into the gap 36.

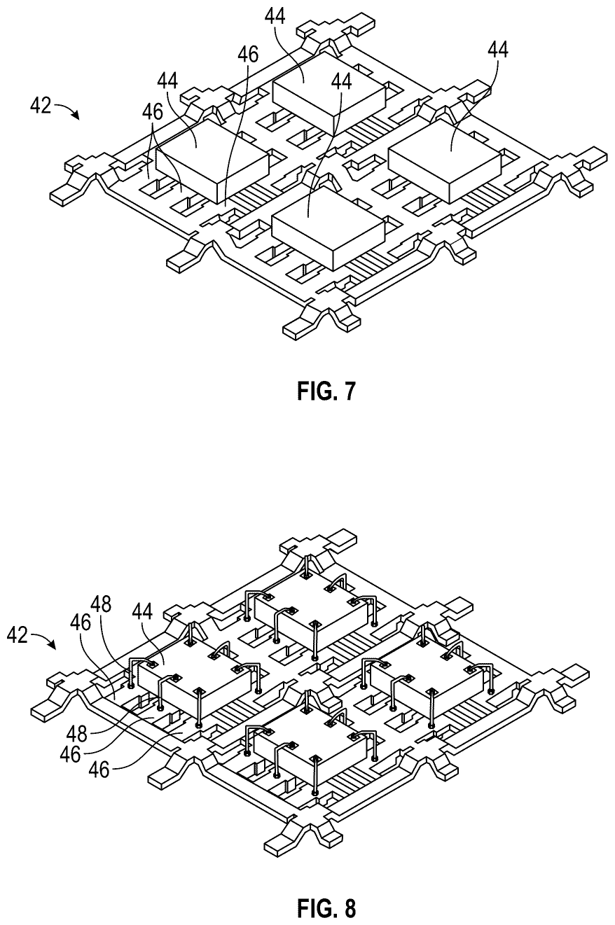

The various semiconductor package implementations disclosed herein may be formed using various methods of forming a semiconductor package. In various implementations, the method includes proving a leadframe with the tie bar and lead configurations disclosed herein. The method then includes coupling one or more semiconductor die to the leadframe. Referring to FIG. 7, an implementation of a leadframe 42 is shown in a reversed view from that illustrated in FIG. 2 where the side of the leadframe 42 that faces the semiconductor die is directed upwardly. FIG. 7 shows four semiconductor die 44 after bonding/coupling to the leads 46 of the leadframe using any of a wide variety of systems and methods, such as, by non-limiting example, soldering, sintering, die attach film, die attach materials, glue, epoxy, or any other material compatible with forming a bond between the material of the semiconductor die 44 and the material of the leadframe 42.

The method may also include forming a plurality of electrical connections using electrical connectors between the semiconductor die 44 and the plurality of leads 46. FIG. 8 illustrates the leadframe 42 following wirebonding to form a plurality of wirebonds 48. Other electrical connector types could also be employed to form electrical connections, including, by non-limiting example, clips, wires, pins, or any other electrical connector type.

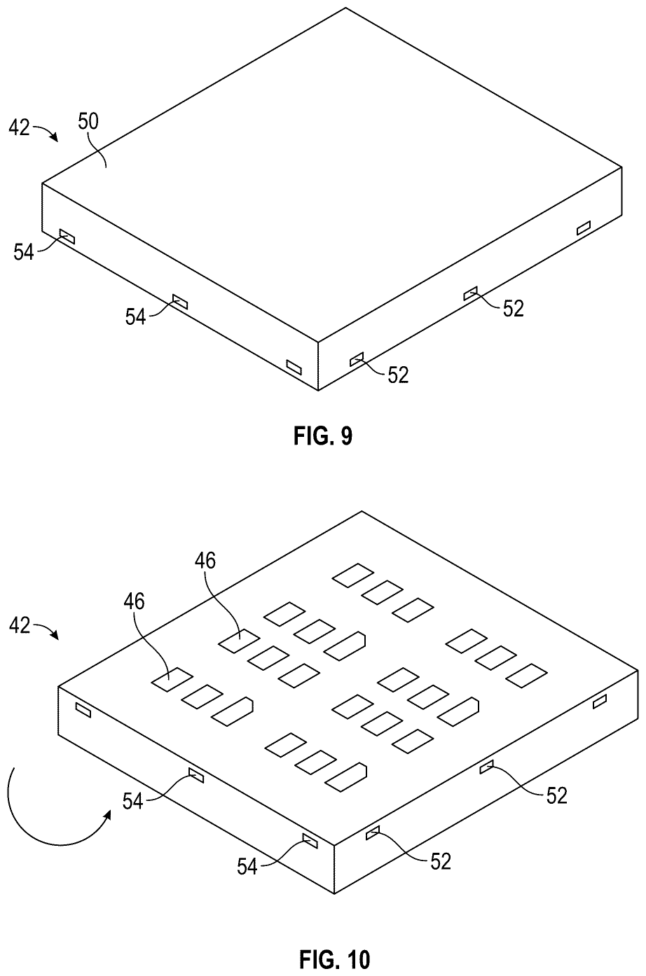

Following formation of the electrical connectors, the method includes applying an electrically insulative material over the leadframe 42, the semiconductor die 44, and the plurality of leads 46. Referring to FIG. 9, the leadframe 42 is illustrated following the application of mold compound 50 which leaves only the ends of the first set of tie bars 52 and second set of tie bars 54 exposed. Following the application of the mold compound 50, the leadframe 42 is then flipped over to bring the side of the leadframe opposite the side to which the semiconductor die are attached to the top (upper side) as illustrated in FIG. 10. In this position, the leadframe 42 is now ready for cutting.

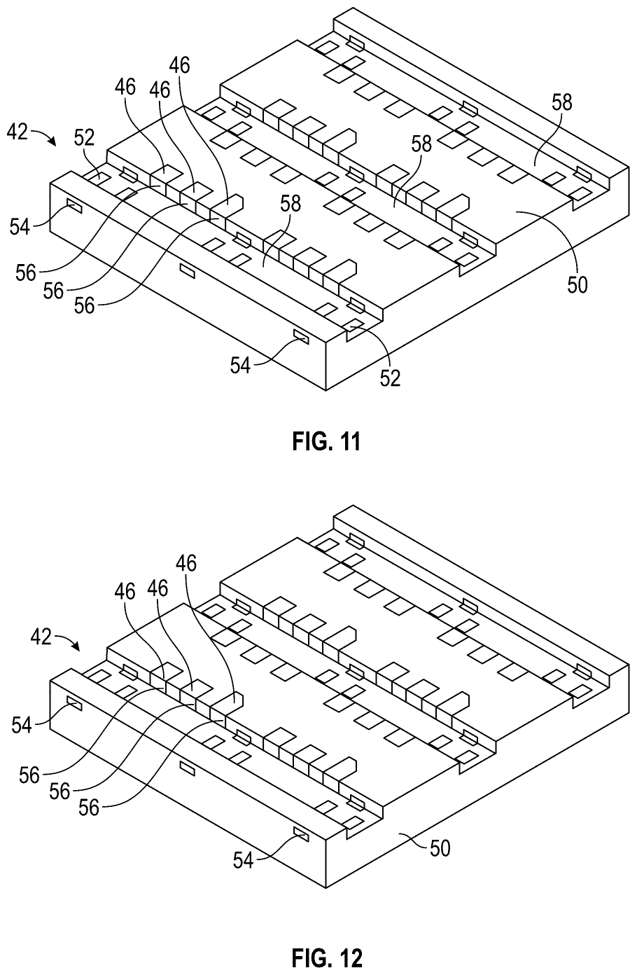

FIG. 11 illustrates the leadframe 42 following formation of a channel/cut 58 into the material of the mold compound 50, cutting of the material of the first set of tie bars 52, and cutting of the leads 46 to form flanks 56. As illustrated in FIG. 11, the channel/cut 58 is a step cut that was formed using a sawing process. The flanks 56 and leads 56 are now exposed through the material of the mold compound 50 along with the ends of the second set of tie bars 54.

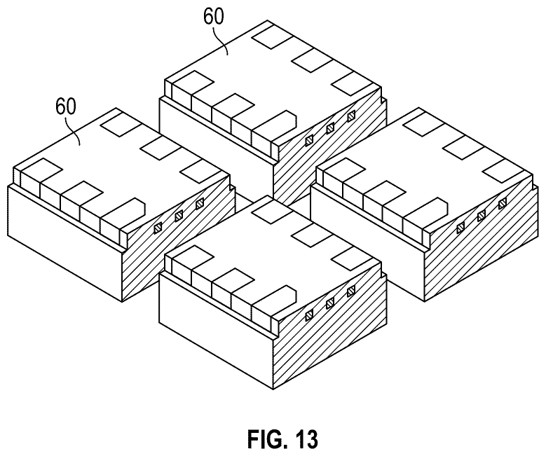

FIG. 12 illustrates the leadframe 42 following an electroplating process involving forming an electric circuit between the ends of the second set of tie bars 54, the leads 46, and the flanks 56. Since the leads are still electrically connected to the second set of tie bars 54 within the mold compound 50, the electric circuit permits the deposition of the electroplated material onto the exposed surfaces of the leads 46 and the flanks 56. Because electroplating of the electroplated material is employed, the thickness of the electroplated material can be controlled up to a desired thickness, which may be about 2 microns or thicker in particular implementations. The material of the electroplated material may be any of a wide variety of materials that can be electrodeposited on the particular material of the substrate, including, by non-limiting example, tin, nickel, gold, palladium, any alloy thereof, any combination thereof, or any other elecroplatable material. In various method implementations the electroplated material may be deposited as one layer or as multiple layers of various materials through different electroplating process steps.

Following electroplating, the method includes singulating semiconductor packages. As illustrated in FIG. 13, a plurality of semiconductor packages 60 are illustrated following singulation in the channel 58 and through the material of the second set of tie bars. As illustrated, this singulation forms the steps/grooves 62 adjacent the flanks 56 of the leads 46. Since these leads and flanks have now been electroplated, issues with wettability caused by corrosion of the base metal of the leads have been substantially eliminated. The packages illustrated in FIG. 13 are ultra dual flat no-lead packages.

In places where the description above refers to particular implementations of semiconductor packages and implementing components, sub-components, methods and sub-methods, it should be readily apparent that a number of modifications may be made without departing from the spirit thereof and that these implementations, implementing components, sub-components, methods and sub-methods may be applied to other semiconductor packages.

What is claimed is:

1. A substrate comprising:
a set of intersecting tie bars forming a grid pattern, wherein each intersection in the set of intersecting tie bars is downset from a plurality of leads coupled within the grid pattern of the set of intersecting tie bars.

2. The substrate of claim 1, wherein a first group of the set of intersecting tie bars is oriented substantially perpendicularly to a second group of the set of intersecting tie bars.

3. The substrate of claim 1, wherein a thickness of the set of intersecting tie bars and the plurality of leads is less than 0.2 mm.

4. The substrate of claim 3, wherein the downset is 0.08 mm or larger.

5. A substrate comprising:
a first set of tie bars;
a second set of tie bars; and
a plurality of leads coupled between the first set of tie bars and the second set of tie bars;
wherein the first set of tie bars intersect with the second set of tie bars; and
wherein each intersection of the first set of tie bars and the second set of tie bars is downset from the plurality of leads.

6. The substrate of claim 5, wherein the first set of tie bars and the second set of tie bars intersect substantially perpendicularly.

7. The substrate of claim 5, wherein a thickness of the first set of tie bars and of the second set of tie bars is less than 0.2 mm.

8. The substrate of claim 5, wherein a thickness of the plurality of leads is less than 0.2 mm.

9. The substrate of claim 5, wherein the downset is 0.08 mm or larger.

10. A method of forming a semiconductor package, the method comprising:
providing a substrate comprising:
a first set of tie bars;
a second set of tie bars; and
a plurality of leads coupled between the first set of tie bars and the second set of tie bars;
wherein the first set of tie bars and the second set of tie bars are downset at a plurality of intersections; and
coupling a semiconductor die to the plurality of leads;
applying an electrically insulative material over the substrate;
forming a channel in the electrically insulative material and forming a flank in each of the plurality of leads;
electroplating the flank of each of the plurality of leads; and
singulating a semiconductor package through cutting the first set of tie bars and second set of tie bars.

11. The method of claim 10, wherein electroplating the flank of each of the plurality of leads further comprises electroplating using the first set of tie bars and the second set of tie bars.

12. The method of claim 10, wherein forming the flank in each of the plurality of leads further comprises cutting entirely through a thickness of each of the plurality of leads.

13. The method of claim 10, wherein forming the channel in the electrically insulative material further comprises partially cutting into the material of the electrically insulative material.

14. The method of claim 10, wherein forming the channel in the electrically insulative material further comprises not cutting the downset of the plurality of intersections.

15. The method of claim 10, wherein singulating the semiconductor package further comprises cutting the channel in the electrically insulative material.

16. The method of claim 10, wherein the substrate is a leadframe.

17. The method of claim 16, wherein the leadframe is a panel.

18. The method of claim 16, wherein the semiconductor package is a leadless semiconductor package.

19. The method of claim 10, wherein, after electroplating, the flank of each of the plurality of leads is a solder wettable flank.

20. The method of claim 10, wherein electroplating the flank of each of the plurality of leads further comprises electroplating the entire flank.
